(19) United States
(12) Patent Application Publication
(10) Pub. No.: US 2016/0188521 A1
(43) Pub. Date: Jun. 30, 2016

(54) CONNECTOR DEVICE TO REMOVABLY CONNECT AND LOCK TO A FRAME

(71) Applicant: HEWLETT PACKARD ENTERPRISE DEVELOPMENT LP, Houston, TX (US)

(72) Inventors: Peter Raymond Szczesniak, Houston, TX (US); Minh H Nguyen, Katy, TX (US)

(21) Appl. No.: 14/910,252

(22) PCT Filed: Sep. 27, 2013
(86) PCT No.: PCT/US2013/062321

§ 371 Date: Feb. 4, 2016

(51) Int. Cl. G06F 13/40; H05K 7/14

(52) U.S. Cl. CPC G06F 13/4068; G06F 13/409; H05K 7/1439

(57) ABSTRACT

A connector device removably connects and locks to a frame to receive a hard drive. The connector device includes a first engagement member, a second engagement member, and a movable lock and release member. The first engagement member includes a first front-face portion, a first back-face portion, and a first channel disposed between the first front-face portion and the first back-face portion. The second engagement member includes a second front-face portion, a second back-face portion, and a second channel disposed between the second front-face portion and the second back-face portion. The movable lock and release member may be placed in a frame cavity of the frame to receive the hard drive. The movable lock and release member is formed to engage a perimeter of the frame cavity to lock the connecter device in an installed position.

### BACKGROUND

A frame may receive hard drives. Connector devices may attach to a frame through fasteners. The connector devices may removably connect to the hard drives in response to the hard drives being received by the frame. The connector devices connected to the hard drives may transmit electrical signals between the hard drives and computing boards.

### BRIEF DESCRIPTION OF THE DRAWINGS

Non-limiting examples are described in the following description read with reference to the figures attached hereto and do not limit the scope of the claims. Dimensions of components and features illustrated in the figures are chosen primarily for convenience and clarity of presentation and are not necessarily to scale. Referring to the attached figures:

FIG. 1 is a block diagram illustrating a connector device according to an example.

FIGS. 2A and 28 are front and rear perspective views illustrating a connector device according to examples, respectively.

FIG. 3A is a perspective view illustrating the connector device of FIG. 2A connected to a frame in an installed position according to an example

FIG. 3B is a cross-sectional view of the connector device of FIG. 3A along line 3B-3B connected to the frame according to an example.

FIG. 4 a perspective view illustrating the connector device of FIG. 2A connected to the frame and a hard drive according to an example.

FIG. 5 is a block diagram illustrating a storage assembly according to an example.

FIG. 6 is a perspective view illustrating a storage assembly according to an example.

FIG. 7 is a flowchart illustrating a method of removably installing a connector device to a frame to receive a hard drive according to an example.

### DETAILED DESCRIPTION

A frame may receive hard drives. Connector devices may attach to a frame through fasteners such as screws, bolts, and the like. The connector devices may removably connect to the hard drives in response to the hard drives being inserted into the frame. The connector devices may transmit power signals and/or data signals between the hard drives and computing boards. The use of fasteners to attach connector devices to the frame may increase the numbers of parts, installation time, cost, and misalignment of the connector device installation.

In examples, a connector device removably connects and locks to a frame to receive a hard drive. The connector device includes, amongst other things, a first engagement member a second engagement member, and a movable lock and release member. The first engagement member includes a first front-face portion, a first back-face portion, and a first channel disposed between the first front-face portion and the first back-face portion. The second engagement member includes a second front-face portion, a second back-face portion, and a second channel disposed between the second front-face portion and the second back-face portion. The movable lock and release member may be placed in a frame cavity of a frame. For example, the frame may removably receive a hard drive.

The electrical insert member may electrically connect to the hard drive inserted into the frame. The first and second channels are formed to engage a frame edge and slide the connector device to the installed position, the first and second front-face portions are formed to engage a front side of the frame, the first and second back-face portions are formed to engage a back side of the frame, and the movable lock and release member is formed to engage the perimeter of the frame cavity to lock the connector device in the installed position. Thus, the connector devices may removably attach to the frame in a self locking manner without the use of fasteners. Accordingly, the connector devices may attach to the frame by reducing the numbers of parts, installation time, cost, and misalignment of the connector device installation.

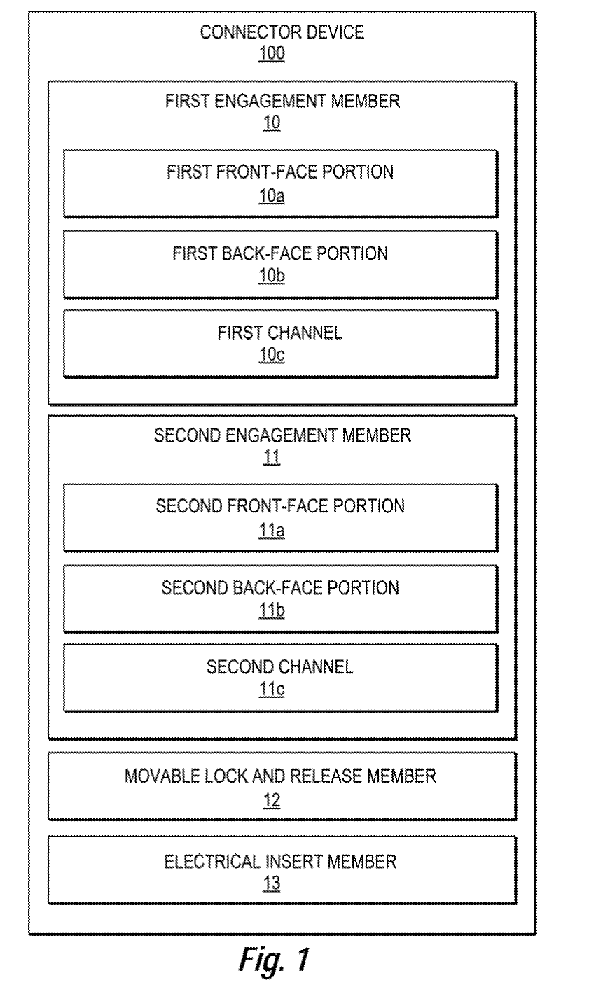

FIG. 1 is a block diagram illustrating a connector device according to an example. In some examples, the connector device 100 may removably connect and lock to a frame to receive a hard drive. The connector device 100 includes a first engagement member 10, a second engagement member 11, a movable lock and release member 12, and an electrical insert member 13. The first engagement member 10 includes a first front-face portion 10a, a first back-face portion 10b, and a first channel 10c disposed between the first front-face portion 10a and the first back-face portion 100. The second engagement member 11 includes a second front-face portion 11a, a second back-face portion 11b, and a second channel 11c disposed between the second front-face portion 11a and the second back-face portion 11b.

Referring to FIG. 1, in some examples, the movable lock and release member 12 may be placed in a frame cavity. For example, the movable lock and release member 12 may be placed in a corresponding frame cavity 312 in order to connect the connector device 100 to frame. The first and second channels 10c and 11c are formed lo engage a frame edge and slide the connector device 100 to an installed position, the first and second front-face portions 10a and 11a are formed to engage a front side of the frame, the first and second back-face members 10b and 11b are formed to engage a hack side of the frame, and the movable lock and release member 12 is formed to engage a perimeter of the frame cavity to lock the connector device 100 in the installed position.

Referring to FIG. 1, in some examples, the electrical insert member 13 may electrically connect to the hard drive inserted into the frame. That is, a corresponding electrical connector on the hard drive may connect to the electrical insert member 13 of the connector device 200 upon the insertion of the hard drive info the frame. In some examples, the hard drive may be removably connected to the frame and/or the connector device 200.

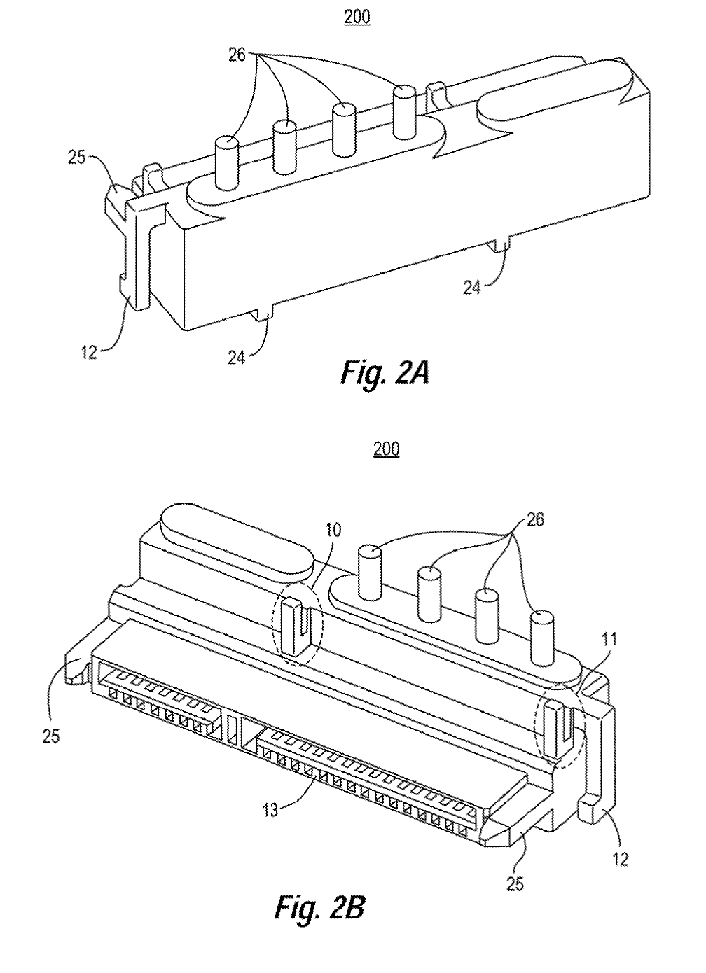

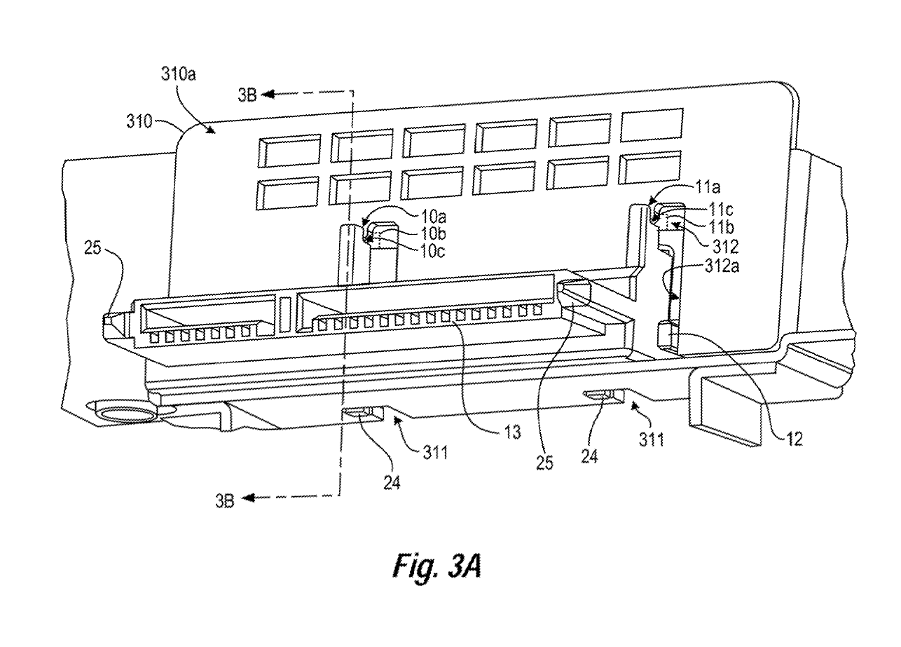

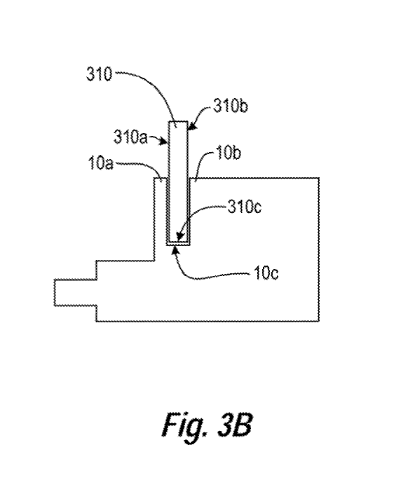

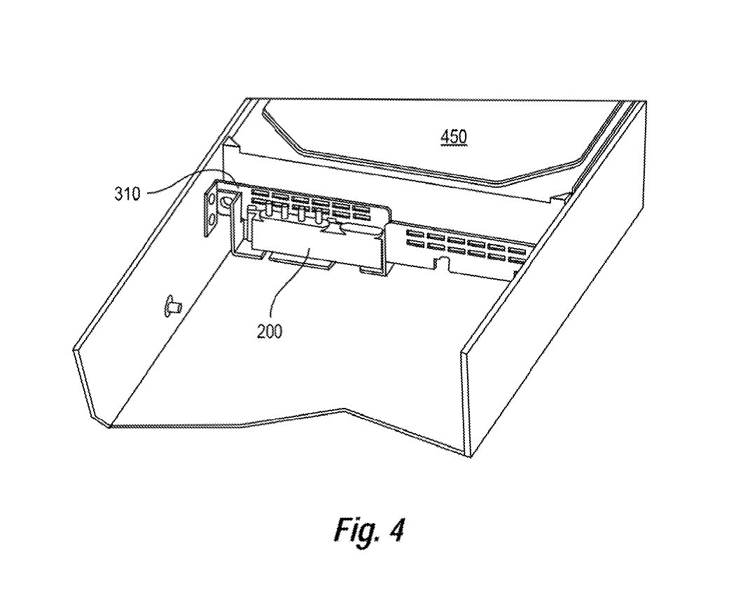

FIGS. 2A and 2B are front and rear perspective views illustrating a connector device according to examples, respectively. FIG 3A is a perspective view illustrating the connector device of FIG. 2A connected to a frame in an installed position according to an example. FIG 3B is a cross-sectional view of the connector device of 3A along line 3B-3B connected to the frame according to an example. FIG. 4 is a perspective view illustrating the connector device of FIG. 2A connected to the frame and a hard drive according to an example. A connector device 200 may include the first engagement member 10, the second engagement member 11, the movable lock and release member 12, and the electrical insert member 13 as previously described with respect to the connector device 100 of FIG. 1.

Referring to FIGS. 2A-4, in some examples, the connector device 200 may also include a guide member 24, an insertion member 25, and wires 26 The guide member 24 may engage a guide slot 311 of the frame 310 to direct the connector device 200 to and from the installed position. The installed position, for example, is a position in which the connector device 200 is placed with respect to the frame 310 to receive a hard drive 450 that is inserted into the frame 310. The frame 310 for example, may be a shelving structure to receive the hard drive 450. In some examples, the shelving structure may include a plurality of connector devices 200 to receive a plurality of hard drives 450. In some examples, the connector device 200 may include a plurality of guide members 24 and a plurality of insertion members 25. The guide slot 311 may engage the guide member 24 to direct the connector device 200 into and out of the installed position.

Referring to FIGS. 2A-4, in some examples, the insertion member 25 may engage and secure the hard drive 450 to the connector device 200 in response to insertion of fie hard drive 450 to the frame 310. That is, the sliding of the hard drive 450 into the frame 310 may enable the insertions member 25 of the connector device 200 to be inserted into corresponding receiving areas (not illustrated) of the hard drive 450. The insertion member 25 may enable the hard drive to be secured to the connector device 200. The connector device 200 may be in a form of a serial advanced technology attachment (SATA) connector. In some examples, wires 26 may connect to the electrical insert member 13 of the connector device 200 to provide power and/or data between a computing board and the hard drive 450 to which the electrical insert member 13 of the connector device 200 may be attached.

deferring to FIGS, 2A-4, in some examples, the movable lock and release member 12 is formed to engage the perimeter 312a of the frame cavity 312 to lock the connector device 200 in the installed position. Additionally, the movable lock and release member 12 is formed to disengage the perimeter 312a of the frame cavity 312 to unlock the connector device 200 from the installed position. That is, the movable lock and release member 12 may be moved away from the perimeter 312a of the frame cavity 312 to unlock the connector device 200 and provide clearance within the frame cavity 312 for the connector device 200 to slide end shift away from the installed position to be removed from the frame 310.

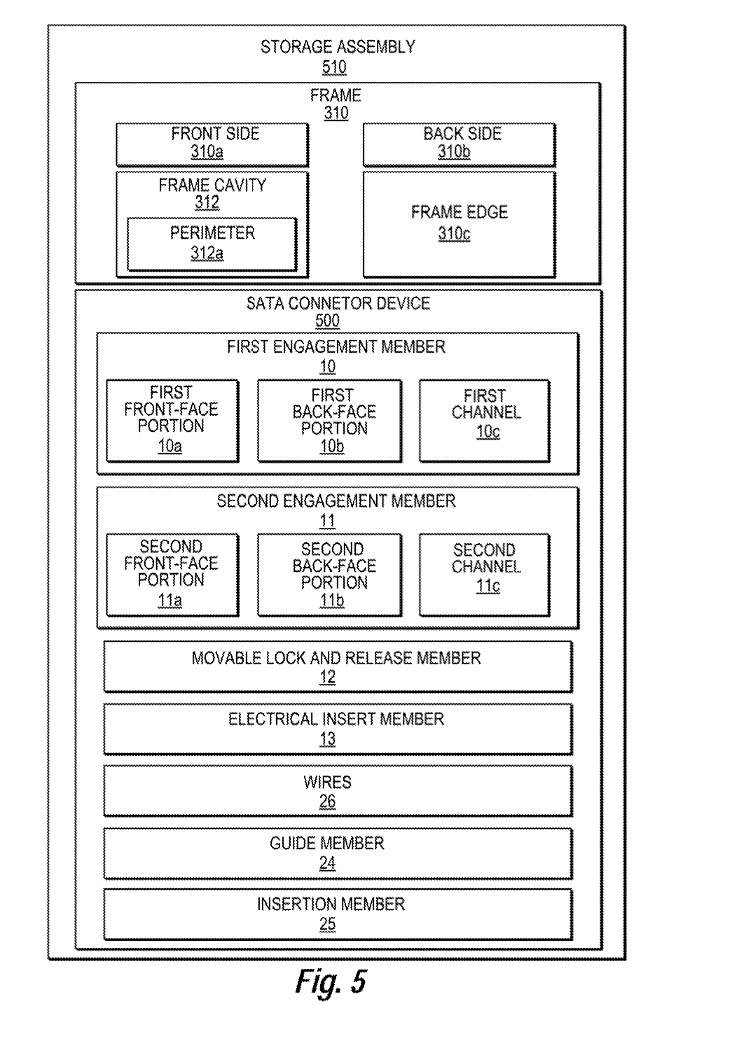

FIG. 5 is a block diagram illustrating a storage assembly according to an example. In some examples, a storage assembly 510 includes a frame 310 and a serial advanced technology attachment (SATA) connecter device 500. The frame 310 may removably receive a SATA hard drive. The frame 310 may include a from side 310a, a back side 310b, a frame cavity 312 having a perimeter 312a, and a frame edge 310c. The SATA connector device 500 may removable connect to the frame 310. The SATA connector device 500 may include a first engagement member 10, a second engagement member 11, a movable lock and release member 12, and an electrical insert member 13.

Referring to FIG. 5, in some examples, the first engagement member 10 may include a first front-face portion 10a, a first back-face portion 10b, and a first channel 10c disposed between the first front-face portion 10a and the first back-face portion 10b. The second engagement member 11 may include a second front-face portion 11a, a second back-face portion 11b, and a second channel 11c disposed between the second front-face portion 11a and the second back-face portion 11b.

Referring to FIG. 5, in some examples, the movable lock and release member 12 may be placed in the frame cavity 312. The electrical insert member 13 may electrically connect to the SATA hard drive inserted into the frame 310. In some examples, the SATA hard drive may be removably inserted into the frame 310. In some examples, wires 26 may connect to the electrical insert member 13 of the SATA connector device 600 to provide power and/or data between a computing board and a respective SATA hard drive to which the electrical insert member 13 of the SATA connector device 500 is attached. The first and second channels 10c and 11c are formed to engage the frame edge 310c and slide the SATA connector device 500 to an installed position, the first and second front-face portions 10a and 11a are formed to engage the front side 310a of the frame 310, the first and second back-face portions 10b and 11b are formed to engage the back side 310b of the frame 310, and the movable lock and release member 12 is formed to engage the perimeter 312a of the frame cavity 312 to lock the SATA connector device 500 in the installed position.

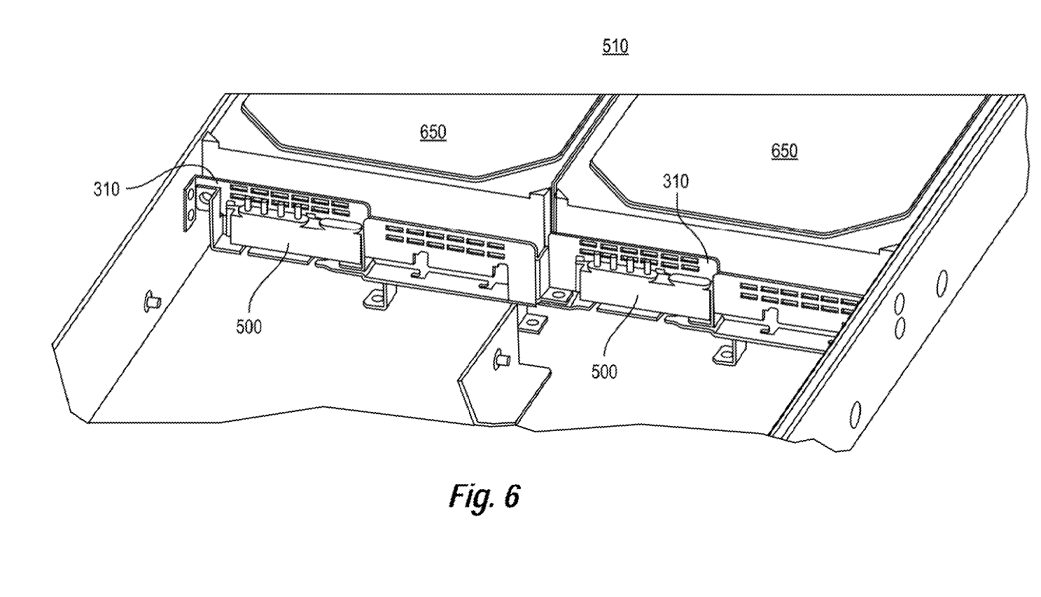

FIG. 6 is perspective view illustrating the storage assembly of FIG. 5 according to an example. In some examples, a storage assembly 510 Includes the frame 310 and a plurality of me serial advanced technology attachment (SATA) connector devices 500 previously discussed with respect to FIG. 5. Referring to FIGS. 5 and 6 some examples, the storage assembly mu may also include a guide member 24 and an insertion member 25 for a respective SATA connector device 500. In some examples, the connection device 500 may Include a plurality of guide members 24 and a plurality of insertion members 26.

Referring to FIGS. 5 and 6, in some examples, the guide member 24 may engage a guide slot 311 of the frame 310 to direct the SATA connector device 500 to and from the installed position. The insertion member 25 may engage and secure the respective SATA hard drive 650 to the respective SATA connector device 500 in response to insertion of the respective SATA hard drive 850 to the frame 310. The movable lock and release member 12 is formed to engage a perimeter 312a of the frame cavity 312 to took the respective SATA connector device 500 in the installed position. Additionally, the movable lock and release member 12 is formed to disengage the perimeter 312a of the frame cavity 312 to unlock the respective SATA connector device 500 from the installed position. That is, the movable lock and release member 12 may be manually moved from the perimeter 312a of the frame cavity 312 to create a clearance therein for the connector device 200 to slide away from the installed position.

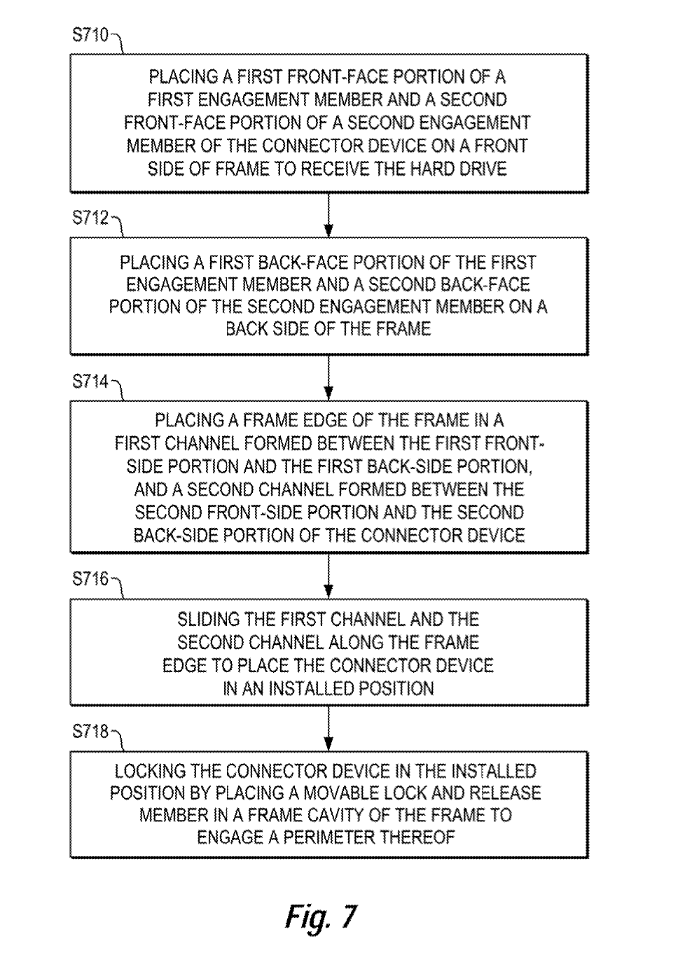

FIG. 7 is a flowchart illustrating a method of removably installing a connector device to a frame to receive a hard drive according to an example In some examples, the modules, assemblies, and the like, of the connector devices 100, 200, and 500 and storage assemblies 510 and 610 previously discussed with respect to FIGS. 1-6 may be used to implement the method of FIG. 7. Referring to FIG. 7, in block S710, a first front-face portion of a first engagement member and a second front-face portion of a second engagement member of the connector device are placed on a front side of the frame to receive the hard drive. In block S712, a first back-face portion of the first engagement member and a second back-face portion of the second engagement member are placed on a back side of the frame. In block S714, a frame edge of the frame is placed in a first channel formed between the first front-side member and the first back-side member, and a second channel formed between the second front-side member and the second back-side member of the connector device, in block S716, the first channel and the second channel are slid along the frame edge to place the connector device in an installed position. In block S718, the connector device is locked in the installed position by placing a movable lock and release member in a frame cavity of the frame to engage a perimeter thereof.

The method may also include unlocking the connector device from the installed position by disengaging the movable look and release member from the perimeter of the frame cavity. The method may also include electrically connecting an electrical insert member of the connector device to the hard drive in response to insertion of the hard drive to the frame. The method may also include engaging a guide slot of the frame by a guide member of the connector device to direct the connector device to and from the installed position. The method may also include engaging and securing the hard drive to the connector device by a plurality of insertion members of the connector device in response to insertion of the hard drive to the frame.

It is to be understood that the flowchart of FIG. 7 illustrates architecture, functionality, and/or operation of examples of the present disclosure. If embodied in software, each block may represent a module, segment, or portion of code that includes one or more executable instructions to implement the specified logical function(s). If embodied in hardware, each block may represent a circuit or a number of interconnected circuits to implement the specified logical function(s). Although the flowchart of FIG. 7 illustrates a specific order of execution, the order of execute may differ from that which is depicted. For example, the order of execution of two or more blocks may be rearranged relative to the order illustrated. Also, two or more blocks illustrated in succession in FIG. 7 may be executed concurrently or with partial concurrence. All such variations are within the scope of the present disclosure.

The present disclosure has been described using non-limiting detailed descriptions of examples thereof that are not intended to limit the scope of the general inventive concept. It should be understood that features and/or operations described with respect to one example may be used with other examples and that not all examples have ail of the features and/or operations illustrated in a particular figure or described with respect to one of the examples. Variations of examples described occur to persons of the art. Furthermore, the terms “comprise,” “include,” “have” and their conjugates, shall mean, when used in the disclosure and/or claims, “including but not necessarily limited to.”

It is noted that some of the above described examples may include structure, acts or details of structures and acts that may not be essential to the general inventive concept and which are described for illustrative purposes. Structure and acts described herein are replaceable by equivalents, which perform the same function, even if the structure or acts are different, as known in the art. Therefore, the scope of the general inventive concept is limited only by the elements and limitations as used in the claims.

What is claimed is:

1. A connector device to removably connect and look to a frame to receive a hard drive, the connector device comprising:
a first engagement member including a first front-face portion, a first back-face portion, and a first channel disposed between the first front-face portion and the first back-face portion;
a second engagement member including a second front-face portion, a second back-face portion, and a second channel disposed between the second front-face portion and the second back-face portion;
a movable look and release member to be placed in a frame cavity; and
an electrical insert member to electrically connect to the hard drive inserted into the frame; and
wherein the first and second channels are formed to engage a frame edge end slide the connector device to an installed position, the first and second front-face portions are formed to engage a front side of the frame, the first and second back-face portions are formed to engage a back side of the frame, and the movable lock and release member is formed to engage the perimeter of the frame cavity to lock the connector device in the installed position.

2. The connector device of claim 1, wherein the movable took and release member is formed to disengage the perimeter of the frame cavity to unlock the connector device from the installed position.

3. The connector device of claim 1, further comprising:
an insertion member to engage and secure the hard drive to the connector device in response to insertion of the hard drive to the frame.

4. The connector device of claim 1, further comprising:
a guide member to engage a guide slot of the frame to direct the connector device to and from the installed position.

5. The connector device of claim 2, wherein the connector device further comprises:
a plurality of guide members to engage respective guide slots of the frame to direct the connector device to and from the installed position; and
a plurality of insertion members to engage and secure the hard drive to the connector device in response to insertion of the hard drive to the frame.

6. The connector device of claim 1, further comprising a serial advanced technology attachment (SATA) connector.

7. A storage assembly, comprising:
a frame to removably receive a serial advanced technology attachment (SATA) hard drive, the frame including a front side, a back side, a frame cavity having a perimeter, and a frame edge; and
a SATA connector device to removable connect to the frame, the SATA connector device including:
a first engagement member Including a first front-face portion, a first back-face portion and a first channel disposed between the first front-face portion end the first back-face portion;
a second engagement member including a second front-face portion, a second back-face portion, and a second channel disposed between the second front-face portion and the second back-face portion;
a movable lock and release member to be placed in the frame cavity; and
an electrical insert member to electrically connect to the SATA hard drive inserted into the frame; and
wherein the first and second channels ere formed to engage the frame edge and slide the SATA connector device to an installed position, the first and second front-face portions are formed to engage the front side of the frame, the first and second back-face portions are formed to engage the back side of the frame, and the movable lock and release member is formed to engage the perimeter of the frame cavity to look the SATA connector device in the installed position.

8. The storage assembly of claim 7, wherein the movable lock and release member is formed to disengage the perimeter of the frame cavity to unlock the SATA connector device from the installed position.

9. The storage assembly of claim 7, further comprising:
a guide member to engage a guide slot of the frame to direct the SATA connector device to and from the installed position.

10. The storage assembly of claim 7, further comprising:
an insertion member to engage and secure the SATA hard drive to the SATA connector device in response to insertion of the SATA hard drive to the frame.

11. A method of removably installing a connector device to a frame to receive a hard drive, the method comprising:
placing a first front-face portion of a first engagement member and a second front-face portion of a second engagement member of the connector device on a front side of the frame to receive the hard drive;
placing a first back-face portion of the first engagement member and a second back-face portion of the second engagement member on a back side of the
placing a frame edge of the frame in a first channel formed between the first front-side member and the first back-side member, and a second channel formed between the second front-side member and the second back-side member of the connector device;
sliding the first channel end the second channel along the frame edge to place the connector device in an installed position; and
locking the connector device in the installed position by placing a movable lock and release member in a frame cavity of the frame to engage a perimeter thereof.

12. The method of claim 11, further comprising;
unlocking the connector device from the installed position by disengaging the movable lock and release member from the perimeter of the frame cavity.

13. The method of claim 11, further comprising:
electrically connecting an electrical insert member of the connector device to the hard drive in response to insertion of the hard drive to the frame.

14. The method of claim 11, further comprising;
engaging a guide slot of the frame by a guide member of the connector device to direct the connector device to and from the installed position.

15. The method of claim 11, further comprising:
engaging and securing the hard drive to the connector device by an insertion member of the connector device in response to insertion of the hard drive to the frame.
